(19) United States
(12) Patent Application Publication
(10) Pub. No.: US 2025/0149294 A1
(43) Pub. Date: May 8, 2025

(54) PLASMA PROCESSING METHOD

(71) Applicant: HITACHI HIGH-TECH CORPORATION, Minato-ku,Tokyo (JP)

(72) Inventors: Juhyun NAM, Tokyo (JP); Masato ISHIMARU, Tokyo (JP); Shota TAHARA, Tokyo (JP)

(21) Appl. No.: 18/282,183

(22) PCT Filed: Jul. 25, 2022
(86) PCT No.: PCT/JP2022/028584

§ 371 Date: Sep. 14, 2023

(51) Int. Cl. H01J 37/32; H01L 21/3065; H01L 21/762

(52) U.S. Cl. CPC H01J 37/32146; H01L 21/3065; H01L 21/76224; H01J 2237/332; H01J 2237/334

(57) ABSTRACT

A method for forming shallow trench isolation, including a first step of etching silicon by plasma; a second step of depositing a film containing a silicon element on a mask; a third step of etching the silicon by plasma such that an etching shape becomes perpendicular; and a fourth step of depositing a film containing SiO on the mask, in which the first step to the fourth step are repeated a predetermined number of times, the plasma in the third step is generated by radio frequency power modulated by a first pulse, the third step is performed while radio frequency power modulated by a second pulse is supplied to a sample having the silicon as a substrate, and a frequency of the first pulse in the third step is higher than a frequency of the second pulse in the third step.

### TECHNICAL FIELD

The present invention relates to a plasma processing method.

### BACKGROUND ART

In recent years, a semiconductor device has been highly integrated, and a transistor having a three-dimensional structure, which is called a fin field effect transistor (hereinafter, also referred to as “Fin-FET”), has been put into practical use. Development of a Gate-All-Around (hereinafter, also referred to as “GAA”) structure, which is an advanced version of this structure, is also underway, in which a gate is covered by four surfaces of a channel, that is, an upper surface, a left surface, a right surface, and a lower surface. When further miniaturization and a higher aspect ratio of such a semiconductor device are advancing and formation of a pattern having a more complicated shape is expected, it is required to construct a vertical processing process having high selectivity corresponding material and a new structure in a manufacturing process of the semiconductor device, in particular, a dry etching technique.

For example, in the etching of a shallow trench isolation (hereinafter, also referred to as “STI”) structure of the Fin-FET, since the structure has a shape whose cross-sectional area changes, it is necessary to change conditions for forming an etching region during the etching. In order to achieve such a shape by dry etching, a larger process window, that is, an enlargement of a range of an optimal process condition is required.

As one of techniques for realizing highly accurate plasma etching, there is a plasma etching method using a pulsed power supply. For example, in a method disclosed in PTL 1, a density and composition of radicals generated by decomposition of a reactive gas by plasma are measured. Power of a plasma generator is pulse-modulated at a constant cycle, and a duty ratio of pulse modulation is controlled based on a measurement result, whereby the density and composition of the radicals are controlled.

PTL 2 discloses a method for forming a via having a high aspect ratio on a silicon substrate by alternately supplying a high power and a low power to a radio frequency coil (antenna coil) for plasma generation, performing a protective f forming by sputtering at the high power, performing etching processing at the low power, and alternately repeating an etching step and a protective film forming step.

### CITATION LIST

### Patent Literature

PTL 1: JPH09-185999A
PTL 2: JP2010-021442A

### SUMMARY OF INVENTION

### Technical Problem

In the etching method using pulse discharge disclosed in the above-described PTL 1, the plasma with a high degree of dissociation generated by plasma is used for etching. Therefore, the process window for controlling an amount of radicals having a deposition property suitable for vertical etching is not sufficient for etching processing suitable for formation of a three-dimensional structure element such as a Fin-FET, that is, etching processing in which conditions for forming an etching region need to be changed during the processing.

In the etching processing disclosed in PTL 2, a radio frequency RF bias power causes local charge, and side surfaces of a hard mask material and the silicon substrate are negatively charged. Therefore, a trajectory of ions is bent, and the ions incident on the side surface of the silicon substrate are increased, and a phenomenon called side etching in which the etching proceeds in a lateral direction occurs. In the etching processing disclosed in PTL 2, a problem that verticality of the etching is impaired is not taken into consideration.

An object of the invention is to provide a technique capable of realizing vertical etching by controlling process conditions.

### Solution to Problem

In order to solve the above problems, one typical plasma processing method according to the invention is a plasma processing method for forming shallow trench isolation. The method includes: a first step of etching silicon by plasma; a second step of depositing a deposited film containing a silicon element on a mask; a third step of etching the silicon by plasma such that an etching shape becomes perpendicular; and a fourth step of depositing a deposited film containing SiO on the mask, in which the first step to the fourth step are repeated a predetermined number of times, the plasma in the third step is generated by radio frequency power modulated by a first pulse, the third step is performed while radio frequency power modulated by a second pulse is supplied to a sample having the silicon as a substrate, and a frequency of the first pulse in the third step is higher than a frequency of the second pulse in the third step.

### Advantageous Effects of Invention

According to the invention, it is possible to realize vertical etching by controlling process conditions. Problems, configurations, and effects other than those described above are clear from the following description of embodiments.

### BRIEF DESCRIPTION OF DRAWINGS

FIG. 1 is a diagram showing a plasma processing apparatus in which a plasma processing method according to a first embodiment of the invention is performed.

FIGS. 2A-2C show schematic views of a state in which the plasma processing method according to the first embodiment is performed.

FIG. 3 is a diagram showing a relation between a pulse frequency when plasma generation power is pulse-modulated and an undercut amount.

FIG. 4 is a diagram showing a relation between a pulse frequency and an undercut amount when bias power is pulse-modulated.

FIG. 5 is a diagram schematically showing a relation between the bias power and a saturated ion current on a wafer that are obtained in the first embodiment.

FIG. 6 is a diagram schematically showing a relation between plasma generation power and a plasma density when a duty ratio is 40% and a pulse frequency is 1300 Hz.

FIG. 7 is a diagram schematically showing a relation between plasma generation power and a plasma density when the duty ratio is 40% and the pulse frequency is 1100 Hz.

FIG. 8 is a diagram showing a flowchart of a method for forming STI.

FIG. 9 is a view schematically showing a part of a silicon substrate before an STI forming step is performed.

FIG. 10 is a view schematically showing a part of the silicon substrate when a first step is performed.

FIG. 11 is a view schematically showing a part of the silicon substrate when a second step is performed.

FIG. 12 is a view schematically showing a part of the silicon substrate when a third step is performed.

FIG. 13 is a view schematically showing a part of the silicon substrate when a fourth step is performed.

FIG. 14 is a view schematically showing a part of the silicon substrate when the first step to the fourth step are repeatedly performed and a trench is etched to predetermined depth.

FIG. 15 is a diagram schematically showing a state in which the first step to the fourth step are repeatedly performed.

FIGS. 16A-16B are diagrams schematically showing a part of a silicon substrate in an etching step as a comparative example.

### DESCRIPTION OF EMBODIMENTS

Hereinafter, embodiments of the invention will be described with reference to the drawings. The invention is not limited to these embodiments. Further, in the description of the drawings, the same parts are designated by the same reference numerals.

When there are a plurality of components having the same or similar functions, the components may be designated by the same reference numerals.

In order to facilitate understanding of the invention, a position, a size, a shape, a range, or the like of each component shown in the drawings may not represent an actual position, size, shape, range, or the like. Therefore, the invention is not necessarily limited to the position, size, shape, range, or the like shown in the drawings.

The expression “pulse-modulated” (hereinafter, also referred to as “modulated by pulse”) means that when there is an output, power is ON, and when there is no output, the power is OFF, and ON and OFF are repeated at a predetermined frequency. The predetermined frequency is also referred to as a “pulse frequency”, a “frequency of pulse”, or a “repetition frequency”. A duty ratio is a ratio of the ON period to a sum of an ON period and an OFF period, that is, one repetition cycle.

The expression “shallow trench isolation” refers to a trench for element isolation formed by etching a silicon substrate or the like.

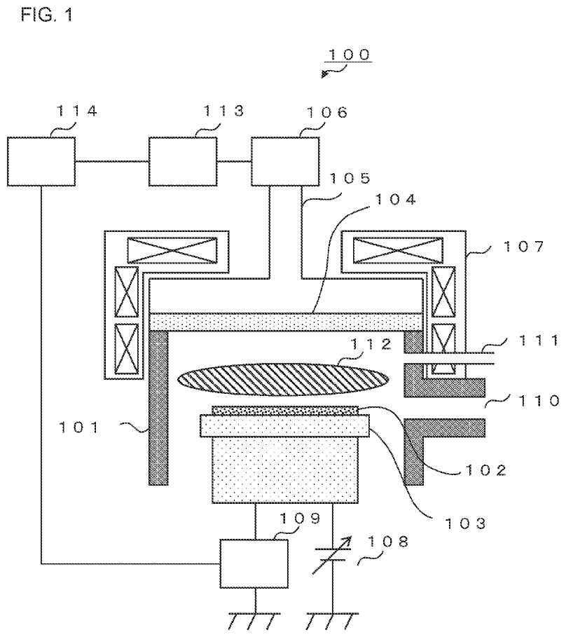

Hereinafter, the embodiments of the invention of the present application will be described with reference to the drawings. FIG. 1 is a diagram showing a plasma processing apparatus in which a plasma processing method according to a first embodiment of the invention is performed.

### First Embodiment

### (Plasma Processing Apparatus)

A plasma processing apparatus 100 includes a vacuum processing chamber 101 in which plasma processing is performed. A lower electrode 103 is provided in the vacuum processing chamber 101, and a wafer mounting surface for holding a wafer 102 is provided in the lower electrode 103. A microwave transmission window 104 is made of a material that transmits microwaves such as quartz while maintaining an inside of the vacuum processing chamber 101 airtight. Microwaves generated from a magnetron (hereinafter, also referred to as a “plasma generator”) 106 pass through the microwave transmission window 104 through a waveguide 105 and propagate into the vacuum processing chamber 101. A solenoid coil 107 is provided around the vacuum processing chamber 101, and generates a magnetic field in the vacuum processing chamber 101. The lower electrode 103 is applied with a voltage from an electrostatic attraction power supply 108 that is connected to the lower electrode 103, and generates an electrostatic force between the wafer 102 and the wafer mounting surface. The wafer 102 is fixed to the wafer mounting surface by the generated electrostatic force.

A magnetron drive power supply (hereinafter, also referred to as “plasma generation power supply”) 113 supplies, to the magnetron 106, radio frequency power (hereinafter, also referred to as “plasma generation power”) for generating plasma. The plasma generation power is also referred to as radio frequency power modulated by a first pulse. A substrate bias power supply 109 supplies, to the lower electrode 103, bias power supplied to a substrate serving as a sample. The bias power is also referred to as radio frequency power modulated by a second pulse. The magnetron drive power supply 113 and the substrate bias power supply 109 are controlled by a power control unit 114.

Further, a wafer loading port 110 is an opening for loading or unloading the wafer 102 into or from the vacuum processing chamber 101. A gas supply port 111 is an opening through which a gas supplied to the vacuum processing chamber 101 is conducted.

The plasma processing apparatus 100 is also provided with vacuum exhaust device. The vacuum exhaust device has a function of depressurizing the vacuum processing chamber 101 to a desired pressure and exhausting, from the vacuum processing chamber 101, a reaction product generated during a plasma process.

Next, a process in a case where the plasma processing is performed using the plasma processing apparatus 100 will be described. The plasma processing apparatus 100 performs a plasma processing method for performing plasma processing on a sample using radio frequency power for generating plasma and bias power for applying a bias to a sample. First, after the inside of the vacuum processing chamber 101 is depressurized, an etching gas is supplied into the vacuum processing chamber 101 from the gas supply port 111, and the inside of the vacuum processing chamber 101 is adjusted to the desired pressure.

Subsequently, the wafer 102 is electrostatically attracted to the wafer mounting surface on the lower electrode 103 by applying a DC voltage of several hundred volts from the electrostatic attraction power supply 108. Thereafter, when the plasma generation power is supplied from the magnetron drive power supply 113, microwaves each having a frequency of 2.45 GHz are oscillated from the magnetron 106. The microwaves are propagated into the vacuum processing chamber 101 through the waveguide 105. When the plasma generation power is not supplied, the magnetron 106 does not oscillate the microwaves.

The magnetic field is generated in the vacuum processing chamber 101 by the solenoid coil 107, and high-density plasma 112 is generated in the vacuum processing chamber 101 by an interaction between the magnetic field and the oscillated microwaves.

After the plasma 112 is generated, the bias power is supplied from the substrate bias power supply 109 to the lower electrode 103. By supplying the bias power, energy of the ions in the plasma incident on the wafer 102 is controlled, and etching processing on the wafer 102 is controlled.

The plasma generation power supplied to the magnetron 106 is pulse-modulated to generate pulse plasma. The pulse plasma controls dissociation of plasma by repeating an ON case in which there is an output of the plasma generation power and an OFF case in which there is no output, and controls a dissociation state and an ion density of the radicals. In this method, the pulse frequency and the duty ratio related to the pulse-modulated plasma are control parameters. The plasma generated by these control parameters is also referred to as pulse plasma.

An output of the substrate bias power supply 109 is also pulse-modulated, the pulse frequency and the duty ratio can be controlled, and the pulse-modulated bias power can be applied to the lower electrode 103. The plasma generation power or the bias power is controlled by the power control unit 114.

In accordance with specification conditions of the plasma processing apparatus 100, a duty ratio of the plasma generation power may be appropriately changed within a range of 10% to 90%, and a duty ratio of the bias power may be appropriately changed within a range of 2% to 90%. In general, the bias power is controlled to be turned on only when the plasma generation power is turned on.

In accordance with the specification conditions of the plasma processing apparatus 100, a pulse frequency of the plasma generation power may be appropriately changed within a range of 100 Hz to 2000 Hz, and a pulse frequency of the bias power may be appropriately changed within a range of 100 Hz to 2000 Hz.

### (Pulse Modulation of Plasma Generation Power and Bias Power)

In the related art, a detailed analysis of the generation of an undercut when both the plasma generation power and the bias power are pulse-modulated is not performed. Therefore, the inventor studies an occurrence of the undercut when both the plasma generation power and the bias power are pulse-modulated,

### (Plasma Processing)

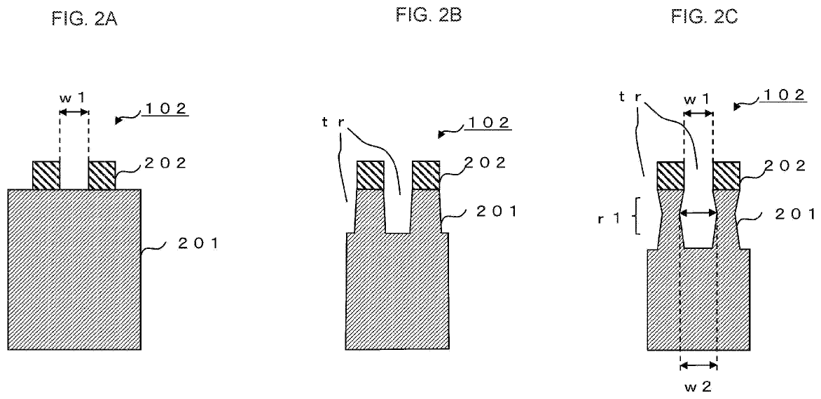

Hereinafter, a plasma processing method for forming shallow trench isolation will be described, FIGS. 2A-2C show schematic views of a state in which the plasma processing method according to the first embodiment is performed. FIG. 2A is a diagram schematically showing a part of a cross section of a silicon substrate 201 before the plasma processing is performed. As shown in FIG. 2A, an initial structure of the silicon substrate 201 is a structure in which masks 202 are formed on the silicon substrate 201. The masks 202 are formed with a pattern having a predetermined gap, and a gap w1 between adjacent masks 202 is 20 nm or less, for example, about 10 nm when used in an STI forming step. In the STI forming step, the silicon substrate 201 is etched by about 130 nm to form trenches each having an aspect ratio of about 6.5. In the present embodiment, each mask 202 is assumed to be a hard mask, but the type of the mask is not limited thereto.

FIG. 2B is a diagram showing how the silicon substrate 201 is etched. Here, portions of the silicon substrate 201 defined by the gaps in the masks 202 are etched to form trenches tr. As processing conditions, for example, a mixed gas containing a halogen gas is used, and pressure is set to 0.5 Pa or less.

FIG. 2C is a diagram showing how the silicon substrate 201 is further etched. Here, a region r1 portion of each trench tr is etched in a direction parallel to a main surface of the silicon substrate 201 to form a neck shape. An occurrence of such a neck shape is called an occurrence of an undercut. When a width of the gap between the masks 202 is defined as w1 and a widest width of widths of the trench tr is defined as w2, an undercut amount can be evaluated as w2−w1,

### (Relation Between Pulse Modulation and Undercut)

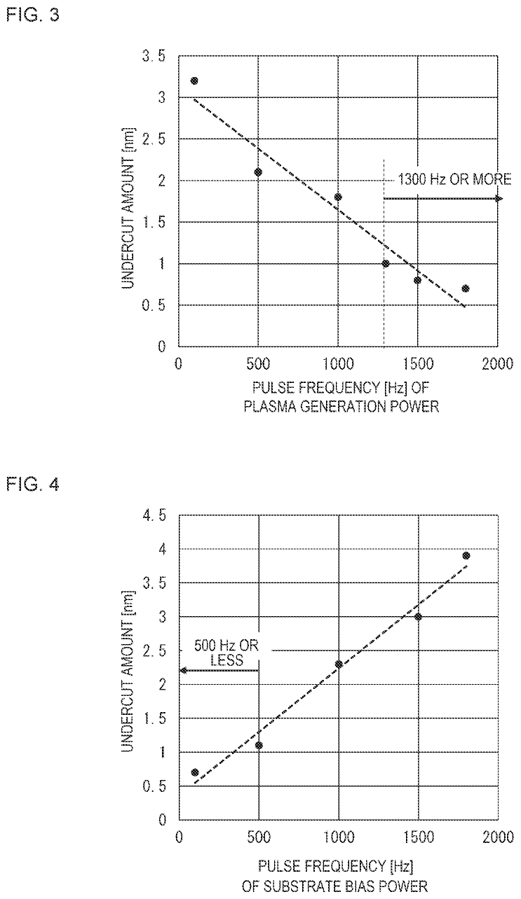

FIG. 3 is a diagram showing a relation between a pulse frequency when the plasma generation power is pulse-modulated and an undercut amount. A power value is set to 900 W, and the duty ratio is set to 40%.

Here, the undercut amount tends to decrease as the pulse frequency increases. When the undercut amount is reduced to about 1 nm, a good trench shape can be obtained, and when the pulse frequency is 1300 Hz or higher, the undercut amount is reduced to 1 nm or less.

FIG. 4 is a diagram showing a relation between a pulse frequency and an undercut amount when the bias power is pulse-modulated. The power value is set to 25 W and the duty ratio is set to 2%.

Here, the undercut amount tends to decrease as the pulse frequency decreases. When the pulse frequency is 500 Hz or less, the undercut amount is reduced to about 1 nm or less.

### Functions and Effects

As described above, the inventor finds that the undercut can be reduced by pulse-modulating both the plasma generation power and the bias power. When the pulse frequency of the plasma generation power is larger than the pulse frequency of the bias power, and the pulse frequency of the plasma generation power is 1300 Hz or more and the pulse frequency of the bias power is 500 Hz or less as an index for pulse modulation, a good result can be obtained from the viewpoint of a trench shape. As described above, in the first embodiment, vertical etching can be realized by pulse-modulating both the plasma generation power and the bias power.

### Second Embodiment

### (State of Plasma Afterglow Discharge)

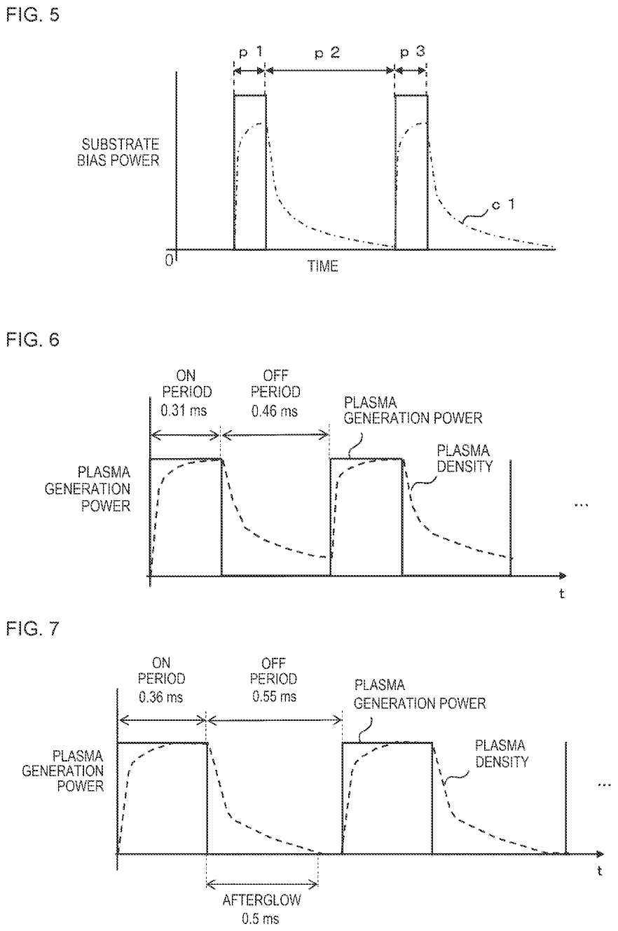

FIG. 5 is a diagram schematically showing a relation between the bias power and a saturated ion current on a wafer that are obtained in the first embodiment. A solid line indicates the bias power and a dashed line indicates the saturated ion current. The saturated ion current is displayed with any value on a vertical axis, and a horizontal axis indicating time is superimposed on a horizontal axis of the bias power. Periods p1 and p3 indicate periods in which an output of the bias power is ON, and a period p2 indicates a period in which the output of the bias power is OFF. In the periods p1 and p3, the saturated ion current rises, suggesting that plasma is being generated. On the other hand, the period p2 suggests a state in which the saturated ion current decreases but does not completely disappear until the subsequent ON period.

Here, the inventor infers that, in the first embodiment, radicals remaining until the plasma disappears are used in a reaction even during an OFF period of the plasma generation power. In the related art, it is known that a state of afterglow discharge, which is a state in which a degree of dissociation of plasma is lowered, occurs during a period from a time during which the plasma generation power is OFF to a time during which the plasma disappears. Here, an etching process performed by plasma is considered.

During a period in which the plasma generation power is ON, a frequency of collision between a processing gas and electrons increases, and the dissociation of the gas proceeds. In this case, most of the radicals in the plasma are radicals having a relatively large adhering coefficient. When the adhering coefficient is large, the radicals tend to adhere to a first colliding surface. For this reason, radicals tend to adhere to trench portions on an upper surface side of the silicon substrate 201 facing the plasma and etching proceeds, while radicals do not easily reach the inner sides of the trenches and the etching does not proceed.

On the other hand, in the state of afterglow discharge during the OFF period of the plasma generation power, the frequency of collision between the gas and the electrons decreases, and a proportion of the gas in a state in which the dissociation does not proceed increases. As the plasma disappears and a density of the plasma decreases, the frequency of collision between electrons and radicals further decreases. In this case, most of the radicals contained in the plasma are radicals each having a relatively small adhering coefficient. The radicals each having a small adhering coefficient are more likely to reach a deep position into the trench without adhering to the first colliding surface. Since unevenness in an amount of etching is prevented in a depth direction of the trench, it is considered that it becomes easier to obtain a trench having a shape perpendicular to a planar direction of the silicon substrate 201.

The inventor makes the above considerations and infers that one of the reasons why the undercut amount is reduced in the first embodiment is that the state of afterglow discharge can be utilized. Therefore, the inventor finds an optimum condition for pulse modulation in order to effectively utilize the state of afterglow discharge. Components corresponding to those of the first embodiment are denoted by the same reference numerals, and descriptions thereof are omitted.

### (Pulse Modulation of Plasma Generation Power)

The inventor observes that the plasma substantially disappears in approximately 0.5 ms after the plasma generation power is OFF. Although values differ depending on various conditions such as a type of gas, a gas pressure, presence or absence of a magnetic field, no significant difference is present in the time until disappearance. Therefore, the remaining time in the state of afterglow discharge is set to 0.5 ms, and the following examination is carried out.

In order to generate many radicals each of which has a small adhering coefficient and contributes to etching in a vertical direction, it is necessary to maximize a total time of the state of afterglow discharge. Table 1 shows calculation results of an ON period and an OFF period of a pulse signal when a duty ratio of the pulse signal is set to 40%, and displays the calculation results in comparison with 0.5 ms as a period of the state of afterglow discharge. As shown here, the OFF period of the plasma generation power at 1300 Hz or more is 0.46 ms, which is shorter than 0.5 ms during which the afterglow discharge disappears. In other words, an OFF time of the first pulse for modulating the plasma generation power is shorter than a time until the afterglow discharge disappears. For this reason, when the plasma generation power is pulse-modulated with the duty ratio of 40% and the pulse frequency of 1300 Hz, the state of afterglow discharge can occupy the entire period in which the plasma generation power is OFF, and radicals each having a small adhering coefficient can be efficiently generated. The relation between the pulse frequency and the duty ratio is not limited to the above values. By making considerations such as those shown here, the pulse frequency and the duty ratio can be adjusted based on the period of the state of afterglow discharge,

TABLE 1

| Pulse | Pulse ON | Pulse OFF | Afterglow |
|---|---|---|---|
| frequency (Hz) | period (ms) | period (ms) | period (ms) |
| 100.0 | 4.00 | 6.00 | 0.50 |
| 1000.0 | 0.40 | 0.60 | 0.50 |
| 1100.0 | 0.36 | 0.55 | 0.50 |
| 1200.0 | 0.33 | 0.50 | 0.50 |
| 1300.0 | 0.31 | 0.46 | 0.50 |
| 1400.0 | 0.29 | 0.43 | 0.50 |
| 1500.0 | 0.27 | 0.40 | 0.50 |
| 1800.0 | 0.22 | 0.33 | 0.50 |
| 2000.0 | 0.20 | 0.33 | 0.50 |

Table 1 visually shows a relation between the pulse frequency and a period of afterglow discharge. FIG. 6 is a diagram schematically showing relation between plasma generation power and a plasma density when the duty ratio is 40% and the pulse frequency is 1300 Hz. FIG. 7 is a diagram schematically showing a relation between plasma generation power and a plasma density when the duty ratio is 40% and the pulse frequency is 1100 Hz. Here, the plasma density is shown in any unit on the vertical axis, and is superimposed on a graph used to describe the relation between the plasma generation power and the plasma density.

As shown in FIG. 6, the state of afterglow discharge is generated in which the plasma density rises and saturates during an ON period of pulse generation power, while the plasma density decreases during an OFF period of the pulse generation power. The OFF period of the pulse generation power is 0.46 ms, which is shorter than the period (0.50 ms) of the state of afterglow discharge. In other words, an OFF time of the first pulse for modulating the pulse generation power is shorter than the time until the afterglow discharge disappears. Therefore, the state of afterglow discharge can occupy the entire period in which the plasma generation power is OFF, and radicals each having a small adhering coefficient can be efficiently generated.

As shown in FIG. 7, the OFF period of the pulse generation power is 0.55 ms, which is longer than the period (0.5 ms) of the state of afterglow. In this case, the state of afterglow discharge disappears during a period in which the pulse power is OFF. As a result, the frequency of collision between the gas and the electrons is further reduced, the dissociation of the gas does not proceed, and an amount of gas remaining in the state at the time of supply increases. Since radicals are not generated, the etching becomes difficult to proceed.

Since the duty ratio of the plasma generation power is set to 40%, the pulse frequency of the plasma generation power for maximizing the state of afterglow discharge is 1300 Hz or more, but the pulse frequency is set in accordance with the duty ratio of the plasma generation power. For example, when the duty ratio of the plasma generation power is set to 20%, if the frequency is constant, the OFF time is longer than that when the duty ratio of the plasma generation power is set to 40%, Therefore, a lower limit of the frequency capable of maximizing the state of afterglow is 1700 Hz, which is higher than that in the case where the duty ratio of the radio frequency power is set to 40% when the pulse frequency is changed in units of 100 Hz. As described above, for example, the pulse frequency of the plasma generation power capable of maximizing the state of the afterglow discharge is set within a range of 300 Hz to 2000 Hz in accordance with the duty ratio of 10% to 90% when the pulse frequency is changed in units of 100 Hz.

### (Pulse Modulation of Bias Power)

It is assumed that most of the ions present in the plasma are accelerated by the bias power, incident vertically on the wafer, and reach the bottom of the trenches each having a high aspect ratio and the bottom of fine patterns. Therefore, it is considered that few ions reach side surfaces of the masks 202 and side surfaces of the trenches of the silicon substrate 201. On the other hand, since electrons are incident on the wafer isotropically at various incident angles, it is assumed that the electrons reaching the bottom of the trenches or the bottom of the fine patterns are less than ions. Therefore, the electrons reach the side surfaces of the masks 202 and the side surfaces of the trenches formed in the silicon substrate 201 and cause a local charge, which is a local charge accumulated in the silicon substrate. When a trajectory of the ions is bent by this local charge, the ions are also incident on the side surfaces, and an amount of side etching to the silicon substrate 201 increases, which causes an abnormal shape such as undercut and bowing.

In order to prevent side etching due to such local charge, it is effective to lower the pulse frequency of the bias power. The higher the pulse frequency, the shorter a duration of the current at one rise and fall. Therefore, when the pulse frequency is too high, a current cannot be generated for a period sufficient to move the charges accumulated on the side surfaces of the masks 202 and the silicon substrate 201 from the wafer 102 to the lower electrode 103. Since a time of the order of sub-ms to ms is required until charges on a wafer surface are released to the lower electrode 103 and the charges accumulated on the wafer are removed, in order to sufficiently move the charges to the lower electrode 103, a time during which the output of the bias power is OFF needs to be the order of ms.

In the present embodiment, the bias power having a duty ratio of 2% is used. As calculated in Table 2, it is desirable to set the pulse frequency to 900 Hz or less in order to make a time during which a pulse output is OFF longer than 1.0 ms. In other words, it is desirable that the OFF time of the second pulse for modulating the bias power is longer than a time during which the local charge is removed.

TABLE 2

| Pulse | Pulse ON | Pulse OFF |
|---|---|---|
| frequency (Hz) | period (ms) | period (ms) |
| 100 | 0.2 | 9.80 |
| 200 | 0.1 | 4.90 |
| 300 | 0.07 | 3.26 |
| 400 | 0.05 | 2.45 |
| 500 | 0.04 | 1.96 |
| 600 | 0.03 | 1.64 |
| 700 | 0.03 | 1.40 |
| 800 | 0.03 | 1.23 |
| 900 | 0.02 | 1.09 |

Since the duty ratio of the bias power is set to 2%, the pulse frequency required to eliminate the local charge is 900 Hz or less, but a value of the pulse frequency differs depending on the setting of the duty ratio. For example, when the duty ratio is set to 50%, a ratio of periods during which the pulse output is OFF is smaller than that when the duty ratio is set to 2%. Therefore, the frequency to make the time required to move the charges to the electrode should be 500 Hz or less. As described above, since the time required to move the charges to the electrode is different depending on a value of the duty ratio, it is desirable that the pulse frequency is set within a range of 100 Hz to 900 Hz with respect to the duty ratio in the range of 2% to 90%.

TABLE 3

| Pulse | Pulse ON | Pulse OFF |
|---|---|---|
| frequency (Hz) | period (ms) | period (ms) |
| 100 | 5.00 | 5.00 |
| 200 | 2.50 | 2.50 |
| 300 | 1.67 | 1.67 |
| 400 | 1.25 | 1.25 |
| 500 | 1.00 | 1.00 |
| 600 | 0.83 | 0.83 |
| 700 | 0.71 | 0.71 |
| 800 | 0.63 | 0.63 |
| 900 | 0.56 | 0.56 |
| 1000 | 0.50 | 0.50 |

### Functions and Effects

In the present embodiment, the inventor finds that as an index for pulse modulation, the pulse frequency of the plasma generation power for maximizing the state of afterglow is set within a range of 300 Hz to 2000 Hz in accordance with the setting of the duty ratio, and the pulse frequency of the bias power for eliminating the local charge of the silicon substrate is set within a range of 100 Hz to 900 Hz in accordance with the setting of the duty ratio. By setting the pulse frequency of the plasma generation power to a higher frequency, the period during which the pulse output is OFF is shortened, and it is easy to maintain the state of afterglow.

By setting the pulse frequency of the bias power to a lower frequency, it is effective to increase a period of the pulse-off and move the charges accumulated in the local charge from the wafer 102 to the lower electrode 103. Accordingly, it is considered that a frequency of the first pulse for modulating plasma generation radio frequency power may be higher than a frequency of the second pulse for modulating a radio frequency bias, and a duty ratio of the first pulse for modulating the plasma generation radio frequency power may be larger than a duty ratio of the second pulse for modulating the radio frequency bias.

As described above, according to the present embodiment, by appropriately setting the duty ratio when the plasma generation power and the bias power are pulse-modulated, the state of plasma afterglow can be used for processing, and vertical etching can be realized.

### Third Embodiment

The inventor proposes an STI forming step based on results of the study of the first embodiment and the second embodiment. Components corresponding to those of the first embodiment and the second embodiment are denoted by the same reference numerals, and descriptions thereof are omitted.

### (Method for Forming STI)

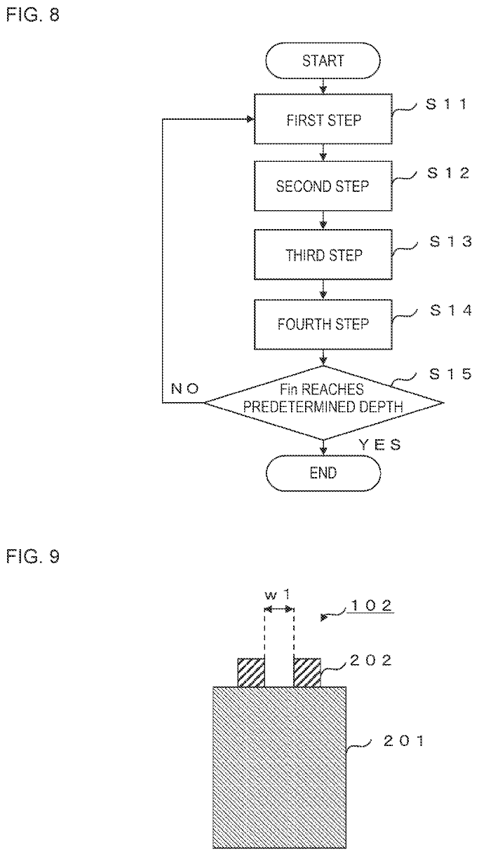

Hereinafter, a method for forming STI will be described. FIG. 8 is a diagram showing a flowchart of the method for forming STI. The flowchart shown here is performed on the wafer 102 in a state in which a mask necessary for forming the STI is formed.

In a first step S11, silicon is etched by plasma. In the first step, a mixed gas containing a halogen gas suitable for etching the wafer is supplied into the vacuum processing chamber 101 to generate plasma, and a sample having silicon as a substrate is etched by the plasma.

In a second step S12, deposited films each containing a silicon element are deposited on masks. In the second step, a mixed gas containing SiCl₄ is supplied into the vacuum processing chamber 101 to form the deposited films each containing a silicon element on the masks.

In a third step S13, the silicon is etched by the plasma such that an etching shape becomes perpendicular. In the third step S134, a mixed gas containing a halogen gas suitable for etching the wafer is supplied into the vacuum processing chamber 101 to generate plasma, and the wafer is vertically etched while preventing an undercut into a pattern by the plasma.

In a fourth step S14, deposited films each containing SiO are deposited on the masks. In the fourth step S14, a mixed gas containing O₂ is supplied into the vacuum processing chamber 101, and surfaces of the deposited films deposited on the masks in the second step are oxidized to form oxide films.

The first step to the fourth step are repeated a predetermined number of times, and it is determined whether a depth of a trench reaches a predetermined depth required for forming the STI, and etching processing is repeated until the depth reaches the predetermined depth (step S15). A step of repeating the first step to the fourth step the predetermined number of times is referred to as an STI forming step of forming the STI of the Fin-FET.

The plasma in the third step S134 is generated by the radio frequency power (hereinafter, also referred to as “plasma generation power”) modulated by the first pulse, and the third step S134 is performed while supplying the radio frequency power (hereinafter, also referred to as “bias power”) modulated by the second pulse to the sample having silicon as a substrate.

### (Schematic Diagram of Wafer at Time of Method for Forming STI)

More specifically, a step of forming the STI will be described. In the present embodiment, a silicon substrate is described as an example of the wafer 102, but the invention is not limited thereto. A substrate made of a material other than the silicon substrate may be used as the wafer 102, or the plasma processing according to the present embodiment may be performed after a semiconductor structure is formed on the silicon substrate.

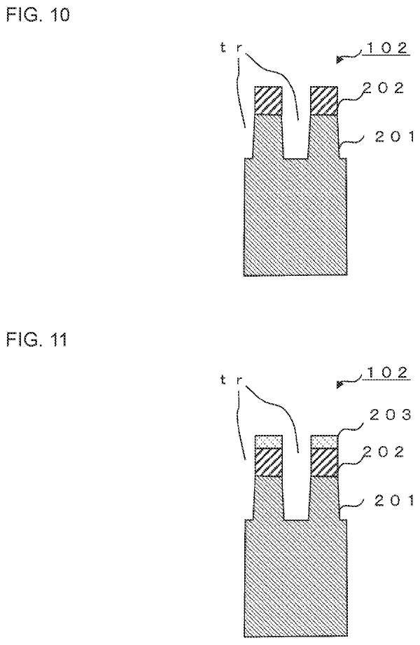

FIG. 9 is a view schematically showing a part of the silicon substrate 201 before an STI forming step is performed. As shown in FIG. 9, the initial structure of the silicon substrate 201 is a structure in which the masks 202 are formed on the silicon substrate 201. The masks 202 are patterned at a predetermined interval, and the interval w1 between the adjacent masks 202 is 20 nm or less, for example, approximately 10 nm. Through the formation of the STI, the silicon substrate is etched by about 130 nm to form trenches each having an aspect ratio of about 6.5. A material and a film thickness of each mask 202 can be appropriately selected. In the present embodiment, the material and the film thickness of each mask 202 are selected in consideration of conditions such as a selection ratio between the mask and the silicon, a layer formed on the mask, ashing performed on the mask in order to etch the silicon substrate 201.

Subsequently, the STI forming step shown in FIG. 8 is performed. Here, Table 4 shows an example of setting conditions of the plasma generation power supply 113 and the substrate bias power supply 109 in each step included in the STI forming step. In the first step S11 and the third step S13, both the plasma generation power supply 113 and the substrate bias power supply 109 perform pulse modulation. In the second step S12 and the fourth step S14, a continuous wave (CW) operation is performed while an output of the plasma generation power supply 113 remains on, and the substrate bias power supply 109 performs pulse modulation.

TABLE 4

| | | Plasma generation power supply | | | Substrate bias power supply | | |
|---|---|---|---|---|---|---|---|
| | | Power | Duty | Pulse | Power | Duty | Pulse |
| | Pressure | value | ratio | frequency | value | ratio | frequency |
| Step | (Pa) | (W) | (%) | (Hz) | (W) | (%) | (Hz) |
| 1 | 0.45 | 1200 | 35 | 2000 | 380 | 25 | 2000 |
| 2 | 0.45 | 1200 | — | — | 60 | 5 | 100 |
| 3 | 0.45 | 900 | 40 | 1800 | 50 | 2 | 100 |
| 4 | 0.45 | 700 | — | — | 60 | 25 | 1000 |

FIG. 10 is a view schematically showing a part of the silicon substrate 201 when the first step S11 is performed. By performing the etching according to the first step S11 on the silicon substrate 201 having the initial structure in which the masks 202 are formed in the first step S11, the trenches tr are formed in portions defined by gaps of the masks 202. As the processing conditions, it is desirable to use a mixed gas containing a halogen gas and set the pressure to 0.5 Pa or less. In the example shown in Table 1, the pressure is set to 0.45 Pa.

The first step S11 is performed while the pulse-modulated bias power is supplied to the lower electrode 103 on which the wafer 102 is mounted. A duty ratio of the first pulse for modulating the plasma generation power for generating plasma is preferably larger than a duty ratio of the second pulse for modulating the bias power supplied to the lower electrode 103.

As shown in Table 4, the plasma generation power supply 113 has a power value of 1200 W. The first pulse for modulating radio frequency power output from the plasma generation power supply 113 has a duty ratio of 35% and a pulse frequency of 2000 Hz. The substrate bias power supply 109 has a power value of 380 W. The second pulse for modulating radio frequency power output from the substrate bias power supply 109 has a duty ratio of 25% and a pulse frequency of 2000 Hz. Both the plasma generation power and the bias power are modulated by pulses. The duty ratio (35%) of the first pulse in the first step S11 is larger than the duty ratio (25%) of the second pulse in the first step S11. The frequency (100 Hz) of the second pulse in the third step S13 is lower than the frequency (2000 Hz) of the second pulse in the first step S11. The duty ratio (2%) of the second pulse in the third step S13 is smaller than the duty ratio (25%) of the second pulse in the first step S11. The frequency (100 Hz) of the second pulse in the second step S12 is lower than the frequency (2000 Hz) of the second pulse in the first step S11. The duty ratio (5%) of the second pulse in the second step S12 is smaller than the duty ratio (25%) of the second pulse in the first step S11.

Here, by making the first step a step of pulse-modulating the plasma generation power and the bias power, a reaction product generated during etching when the plasma power is OFF is exhausted through a vacuum exhaust device. Therefore, it is possible to prevent the reaction product from adhering to the masks 202 and the silicon substrate 201 and forming a deposit. When a gas pressure is reduced, the reaction product generated during etching can be further reduced. For this reason, since the etching is prevented from being hindered by the reaction product, the etching of the silicon substrate in the vertical direction can proceed.

FIG. 11 is a view schematically showing a part of the silicon substrate 201 when the second step S12 is performed. In the second step, a SiCl₄ gas is supplied, plasma is generated using the SiCl₄ gas, and silicon-based deposited films 203 each containing a silicon element are formed on upper surfaces of the masks 202. By providing the deposited film 203 on the upper surfaces of the masks 202, damage to the upper surfaces and side surfaces of the masks 202 can be prevented when the silicon substrate 201 is further deeply etched, and collapse of the pattern of the masks can be prevented. In the second step S12, a size of Cl ions contained in the plasma is large, and the deposition of the deposited film in the trenches tr is prevented. For this reason, although the deposited film can be deposited at portions other than the masks 202, an amount thereof is small enough to be negligible, and therefore, it is not considered in FIG. 11. This also applies to oxide films 204 in the fourth step S14 to be described later, and the Cl ions are contained in the plasma.

As shown in Table 4, the plasma generation power supply 113 has a power value of 1200 W and does not perform pulse modulation. The substrate bias power supply 109 has a power value of 60 W, a duty ratio of 58, and a pulse frequency of 100 Hz.

FIG. 12 is a view schematically showing a part of the silicon substrate 201 when the third step S13 is performed. Here, the trenches tr are formed in a direction perpendicular to the silicon substrate 201. As processing conditions of the third step, any mixed gas containing a halogen gas suitable for etching the silicon substrate is used in the vacuum processing chamber 101. As the halogen gas, for example, a fluorine gas is frequently used since the fluorine gas has high reactivity.

As shown in Table 4, the plasma generation power supply 113 has a power value of 900 W. The first pulse for modulating the plasma generation power output from the plasma generation power supply 113 has a duty ratio of 40% and a pulse frequency of 1800 Hz. The substrate bias power supply 109 has a power value of 50 W. The second pulse for modulating the radio frequency power output from the substrate bias power supply 109 has a duty ratio of 2% and a pulse frequency of 100 Hz.

By pulse-modulating the plasma generation power and the bias power in the same manner as in the first step S11, a reaction product generated during etching when the plasma power is OFF is exhausted through the vacuum exhaust device, and a deposit adhering to the masks 202 and the silicon substrate 201 can be prevented. Further, by lowering the gas pressure, the reaction product during etching decreases, and the silicon substrate can be etched in the vertical direction.

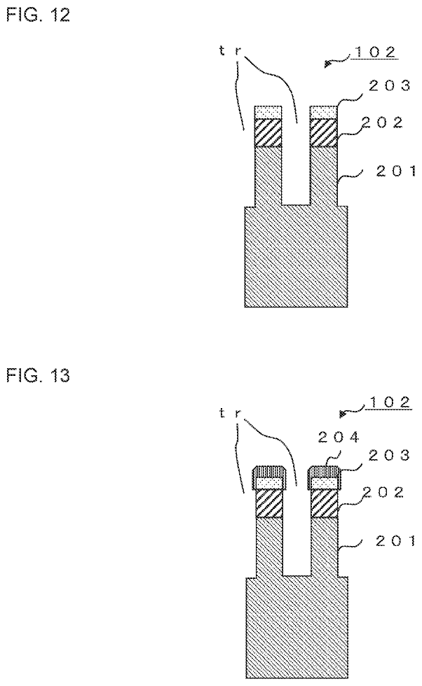

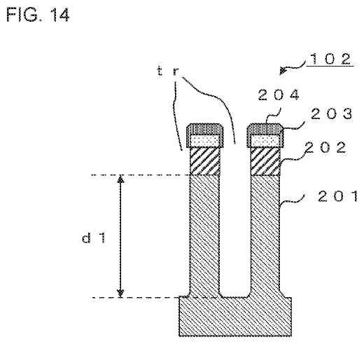

FIG. 13 is a view schematically showing a part of the silicon substrate 201 when the third step S14 is performed. In the fourth step S14, a mixed gas containing Ar and O₂ is supplied, and surfaces of the deposited films 203 generated on the masks 202 in the second step S12 are oxidized to form the oxide films 204. As shown in FIG. 13, by providing the oxide films 204 on the deposited films 203, the damage to the upper surfaces and the side surfaces of the masks 202 can be further prevented when the silicon substrate is further deeply etched, and the pattern of the masks 202 can be prevented from being damaged. Each oxide film 204 contains SiO, but is not limited thereto. The oxide film 204 may contain SiO₂, or may contain other oxides.

As shown in Table 4, the plasma generation power supply 113 has a power value of 700 W and does not perform pulse modulation. The substrate bias power supply 109 has a power value of 60 W, a duty ratio of 25%, and a pulse frequency of 1000 Hz.

FIG. 14 is a view schematically showing a part of the silicon substrate when the first step S11 to the fourth step S14 are repeatedly performed and the trench tr is etched to a predetermined depth d1. Here, the depth d1 of the trench tr can reach a value required to form the STI through the STI forming step.

In the present embodiment, etching is performed by repeating the first step S11 to the fourth step S14 six times, thereby setting the depth of the trench to 130 nm. In the present embodiment, the etching processing is performed until the depth of the trench is 130 nm, but the invention is not limited thereto, and the etching processing may be performed until the depth of the trench reaches a predetermined depth capable of forming the Fin. The depth of the trench, manufacturing conditions, and the number of repetitions of the STI forming step may be examined in advance, and it may be determined that the trench has a desired depth when the STI forming step is performed the predetermined number of times.

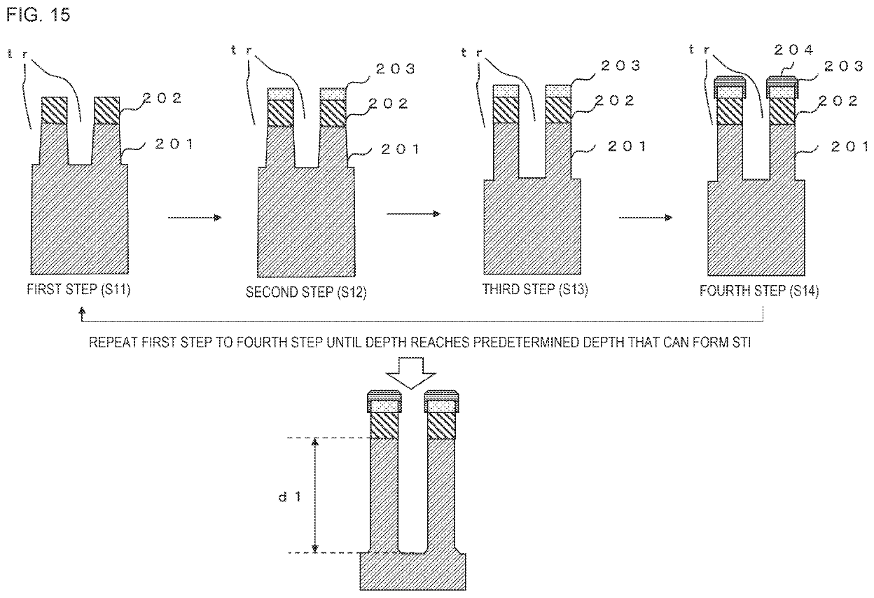

FIG. 15 is a diagram schematically showing a state in which the first step S11 to the fourth step S14 are repeatedly performed. In the first step S11, the trenches tr are formed. In the second step S12, the deposited films 203 are formed on the masks 202. In the third step S13, etching is performed such that the etching shape becomes perpendicular. In the fourth step S14, the oxide films 204 are formed on the deposited films 203. Returning to the first step S11, the deposited films 203 and the oxide films 204 formed on the masks 202 are etched. The first step S11 is set to be performed for a time during which the deposited films 203 and the oxide films 204 are etched. Steps from the first step S11 to the fourth step S14 are performed until the depth of the trench reaches the predetermined depth d1. In the present embodiment, the depth d1 of the trench tr can be set to 130 nm by repeating the first step to the fourth step six times.

### Functions and Effects

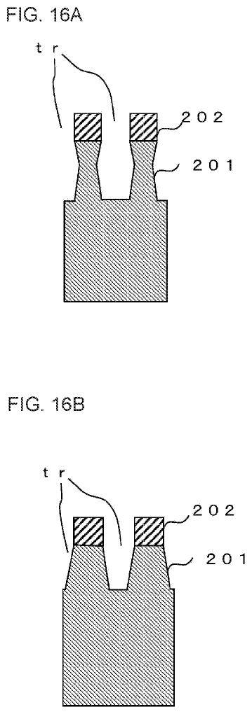

FIGS. 16A-16B are diagrams schematically showing a part of the silicon substrate 201 in an etching step as a comparative example. Here, a case where the trench shape in the etching step is defective is shown. FIG. 16A shows a case where an undercut occurs. The undercut is considered to occur when an influence of isotropic etching occurs strongly. On the other hand, FIG. 16B shows a shape generated when etching proceeds due to radicals each having a large adhering coefficient. When the adhering coefficient is large, the radicals tend to adhere to a first colliding surface. The radicals adhere to trench portions on the upper surface side of the silicon substrate 201 facing the plasma and etching proceeds, while the radicals are less likely to adhere to the inner sides of the trenches and the etching does not proceed. When each trench has a shape having a high aspect ratio, radicals are less likely to enter the inner sides of the trenches. Therefore, the etching does not proceed toward the inner sides of the trenches, sidewalls of the trenches become thicker, and the trenches tr of the silicon substrate 201 are tapered as shown in FIG. 16B.

In contrast, in the present embodiment, radicals whose adhering coefficient is reduced in the third step are used for etching. Accordingly, as shown in FIG. 12, it is possible to perform etching in the vertical direction while maintaining a good shape of each trench tr.

In the present embodiment, in the fourth step, the oxide films 204 are formed on the deposited films 203 on the masks 202. Accordingly, it is possible to prevent the deposited films 203 and the masks 202 from being etched and damaged while the trenches tr are deeply etched.

As described above, according to the present embodiment, vertical etching can be realized by setting process conditions using a type of radicals each having a small adhering coefficient.

The invention is not limited to the embodiments described above, and includes various modifications. For example, the embodiments described above are described in detail for easy understanding of the invention, and the invention is not necessarily limited to those including all the configurations described above. Further, a part of the configuration of one embodiment can be replaced with configurations of another embodiment, and the configurations of another embodiment can be added to the configuration of the embodiment. In addition, a part of the configuration of each embodiment may be added, deleted, or replaced with another configuration.

### REFERENCE SIGNS LIST

101 vacuum processing chamber
102 wafer
103 lower electrode
104 microwave transmission window
105 waveguide
106 magnetron
107 solenoid coil
108 electrostatic attraction power supply
109 substrate bias power supply
110 wafer loading port
111 gas supply port
112 plasma
113 plasma generation power supply
114 power control unit
201 silicon substrate
202 mask
203 deposited film
204 oxide film

1. A plasma processing method for forming shallow trench isolation, the method comprising:
a first step of etching silicon by plasma;
a second step of depositing a deposited film containing a silicon element on a mask;
a third step of etching the silicon by plasma such that an etching shape becomes perpendicular; and
a fourth step of depositing a deposited film containing SiO on the mask, wherein
the first step to the fourth step are repeated a predetermined number of times,
the plasma in the third step is generated by radio frequency power modulated by a first pulse,
the third step is performed while radio frequency power modulated by a second pulse is supplied to a sample having the silicon as a substrate, and
a frequency of the first pulse in the third step is higher than a frequency of the second pulse in the third step.

2. The plasma processing method according to claim 1, wherein
an OFF time of the first pulse in the third step is shorter than a time until afterglow discharge disappears.

3. The plasma processing method according to claim 2, wherein
an OFF time of the second pulse in the third step is longer than a time during which charges accumulated in the sample are removed.

4. The plasma processing method according to claim 3, wherein
a duty ratio of the first pulse in the third step is larger than a duty ratio of the second pulse in the third step.

5. The plasma processing method according to claim 4, wherein
in the second step, the deposited film containing the silicon element is deposited by plasma generated using a SiCl₄ gas.

6. The plasma processing method according to claim 5, wherein
a duty ratio of the first pulse in the first step is larger than a duty ratio of the second pulse in the first step.

7. The plasma processing method according to claim 6, wherein
the frequency of the second pulse in the third step is lower than a frequency of the second pulse in the first step.

8. The plasma processing method according to claim 7, wherein
a duty ratio of the second pulse in the third step is smaller than the duty ratio of the second pulse in the first step.

9. The plasma processing method according to claim 8, wherein
a frequency of the second pulse in the second step is lower than the frequency of the second pulse in the first step.

10. The plasma processing method according to claim 9, wherein
a duty ratio of the second pulse in the second step is smaller than the duty ratio of the second pulse in the first step.

11. The plasma processing method according to claim 10, wherein
the frequency of the first pulse in the third step is a frequency within a range of 300 kHz to 2000 KHz.

12. The plasma processing method according to claim 11, wherein
the frequency of the second pulse in the third step is a frequency within a range of 100 kHz to 900 kHz.
